(19) United States
(12) Patent Application Publication
(10) Pub. No.: US 2025/0318080 A1
(43) Pub. Date: Oct. 9, 2025

(54) DIRECT LIQUID CONTACT ELECTRONICS COOLING SYSTEM WITH MULTIMODE FUNCTIONALITY

(71) Applicant: Louisiana Tech Research Corporation; of Louisiana Tech University Foundation, Inc., Ruston, LA (US)

(72) Inventor: Arden Moore, Ruston, LA (US)

(21) Appl. No.: 19/095,480

(22) Filed: Mar. 31, 2025

Related U.S. Application Data
(60) Provisional application No. 63/574,374, filed on Apr. 4, 2024.

(51) Int. Cl. H05K 7/20

(52) U.S. Cl. CPC H05K 7/20281; H05K 7/20245; H05K 7/20263; H05K 7/20272; H05K 7/20327; H05K 7/20381; H05K 7/20409

(57) ABSTRACT

A system for cooling an electronic component includes an enclosure, a radiator, a pump, a valve, and a tubing network. The enclosure is configured to house the electronic component and to permit a fluid to directly contact the electronic component. The valve selectively permits passage of the fluid to the pump. The tubing network circulates a fluid from the enclosure to at least one of the radiator, the valve, or the pump.

### TECHNICAL FIELD

This disclosure relates generally to cooling systems for integrated circuits, and in particular, to cooling systems which employ direct liquid contact and incorporate multimode functionality to address real-time cooling demands across a variety of workloads and operating environments.

### BACKGROUND

Due to the advancement of integrated circuit technology, particularly in artificial intelligence and machine learning, operational speeds are limited by communication between components. To address this, modern packaging techniques such as multi-chip modules (“MCMs”) with 2.5D and 3D integration aim to enhance communication between critical components by having multiple chips in a single package. Multiple chips may be included either in proximity or atop one another in each MCM. However, this arrangement may lead to challenges such as highly localized heat loads and a large number of conduction-impeding interfaces, resulting in temperature-driven issues such as performance throttling, delamination, cracking, and reduced lifespan.

While high performance cooling solutions for electronics currently exist, most rely on traditional indirect methods such as heat sinks and liquid-cooled cold plates external to the package, and are thus limited by the internal thermal resistances of the package itself. Further, most high-performance cooling solutions are designed primarily to handle the highest heat loads, when in fact, workload and associated thermal power is highly dynamic. As a result, current solutions are inefficient in terms of minimizing size, weight, power, and cost (“SWaP-C”). Therefore, there exists a need for a versatile thermal management system capable of efficiently and effectively cooling components.

### SUMMARY

An aspect of this disclosure provides a system for cooling an electronic component that includes an enclosure, a radiator, a pump, a valve, and a tubing network. The enclosure is configured to house the electronic component and to permit a fluid to directly contact the electronic component. The valve selectively permits passage of the fluid to the pump. The tubing network circulates the fluid from the enclosure to at least one of the radiator, the valve, or the pump.

In another aspect of this disclosure, the enclosure may include an inlet and an outlet. A first portion of the tubing network may connect the outlet of the enclosure and the radiator. A second portion of the tubing network may connect the radiator and the valve. A third portion of the tubing network may connect the valve and the inlet of the enclosure.

In yet another aspect of this disclosure, a fourth portion of the tubing network may connect the valve and the pump. A fifth portion of the tubing network may connect the pump and the inlet of the enclosure. The third portion of the tubing network and the fifth portion of the tubing network may intersect.

In a further aspect of this disclosure, the valve may permit the fluid to enter either the third portion of the tubing network or the fourth portion of the tubing network based at least in part on at least one of a computational or thermal load of the electronic component.

In another aspect of this disclosure, the valve may permit the fluid to enter the pump based at least in part on at least one of a computational or thermal load of the electronic component.

In yet another aspect of this disclosure, the pump may be powered on to propel the fluid through the tubing network based at least in part on at least one of a computational or thermal load of the electronic component.

In a further aspect of this disclosure, the enclosure may be configured to provide a greater volume of fluid to a portion of the electronic component having a greater power density in comparison to a portion of the electronic component having a lower power density.

In another aspect of this disclosure, the system may further include a processor and a memory. The memory may include instructions stored thereon, which, when executed by the processor cause the system to determine at least one of a computational or thermal load of the electronic component and, based at least in part on at least one of the determined computational or thermal load of the electronic component, operate the valve and the pump in accordance with a predetermined mode.

In yet another aspect of this disclosure, the instructions, when executed by the processor, may cause the system to, if the determined computational or thermal load of the electronic component is low-to mid-level, operate in a first mode. In the first mode, the valve may be actuated to prevent the fluid from entering the pump via the tubing network, and the pump may be powered off.

In a further aspect of this disclosure, the instructions, when executed by the processor, may cause the system to, if the determined computational or thermal load of the electronic component is high, operate in a second mode. In the second mode, the valve may be actuated to permit the fluid to enter the pump via the tubing network, and the pump may be powered on.

An aspect of this disclosure provides an enclosure for use with a cooling system for an electronic component. The enclosure includes a mounting surface, one or more walls protruding from the mounting surface, and a lid disposed on the one or more walls. The one or more walls separate the mounting surface and the lid to form a flow cavity therebetween. The flow cavity is configured to house the electronic component, and the flow cavity is configured to pass a fluid over the electronic component to cool the electronic component.

In another aspect of this disclosure, the enclosure may further include an inlet to permit ingress of the fluid. The inlet may be disposed on a wall of the one or more walls.

In yet another aspect of this disclosure, the enclosure may further include an outlet to permit egress of the fluid. The outlet may be disposed on a wall of the one or more walls.

In a further aspect of this disclosure, the mounting surface may further include one or more arms for attachment to a surface.

In another aspect of this disclosure, the one or more arms may extend outward from the one or more walls of the enclosure.

In yet another aspect of this disclosure, a hole may be defined through at least an arm of the one or more arms. The hole may be configured to receive a fastener.

In a further aspect of this disclosure, the lid, on a surface facing the flow cavity, may further include a geometric feature configured to direct the fluid toward a portion of the electronic component having a high power density.

An aspect of this disclosure provides a method of cooling an electronic component within an enclosure. The enclosure is configured to permit direct contact between the electronic component and a fluid. A tubing network is configured to circulate the fluid through the enclosure, a radiator, and at least one of a valve or a pump, before returning the fluid to the enclosure. The valve selectively connects the tubing network to the pump. The method includes determining at least one of a computational or thermal load of the electronic component, and based at least in part on the determined computational or thermal load of the electronic component, operating the valve and the pump in accordance with a predetermined mode.

In another aspect of this disclosure, the method may further include, if the determined computational or thermal load of the electronic component is low-to mid-level, operating in a first mode. The first mode may include circulating the fluid from the enclosure through the radiator, actuating the valve to prevent the fluid from entering the pump, powering the pump off such that the fluid is circulated through the tubing network via natural convection, and returning the fluid to the enclosure from the valve.

In yet another aspect of this disclosure, the method may further include, if the determined computational or thermal load of the electronic component is high, operating in a second mode. The second mode may include circulating the fluid from the enclosure through the radiator, actuating the valve to permit the fluid to enter the pump, powering the pump to propel the fluid through the tubing network, and returning the fluid to the enclosure from the pump.

Further details and aspects of the present disclosure are described in more detail below with reference to the appended drawings.

### BRIEF DESCRIPTION OF DRAWINGS

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 illustrates a schematic diagram of an exemplary direct liquid contact cooling system, in accordance with aspects of this disclosure;

FIG. 2 shows a lid of the direct liquid contact cooling system of FIG. 1, in accordance with aspects of this disclosure;

FIG. 3 is a block diagram of a computing device configured for use with the direct liquid contact cooling system, in accordance with aspects of this disclosure;

FIG. 4A shows the direct liquid contact cooling system of FIG. 1, as implemented into a computer tower, in accordance with aspects of this disclosure;

FIG. 4B is an enlarged view of the lid of the direct liquid contact cooling system of FIG. 4A; and

FIG. 5 is a table showing modes of operation of the direct liquid contact cooling system of FIG. 1, in accordance with aspects of this disclosure.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein. As used herein, the term “radiator” refers to a heat-rejection device, including a radiator, a liquid-liquid heat exchanger, an AC unit, or the like.

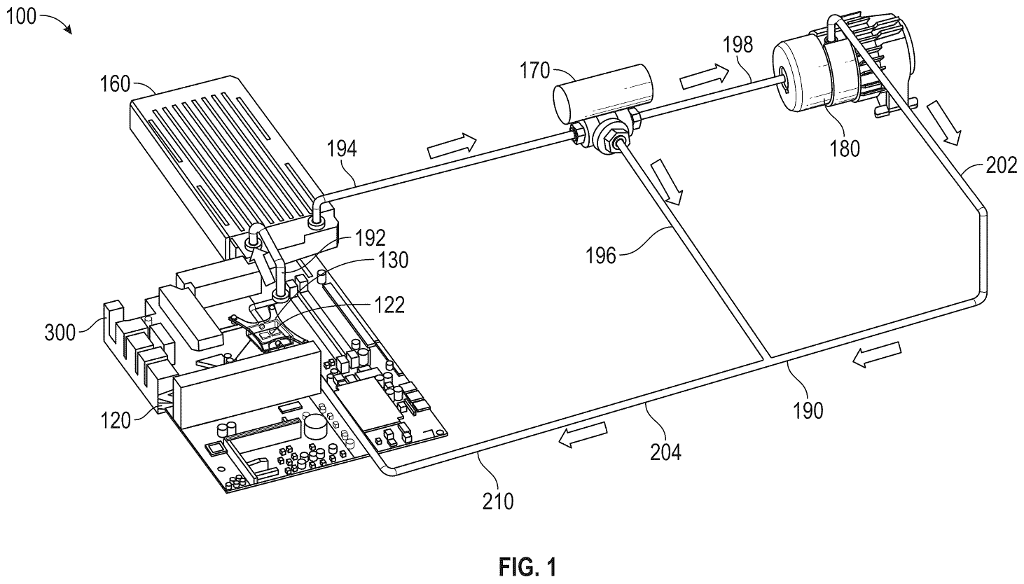

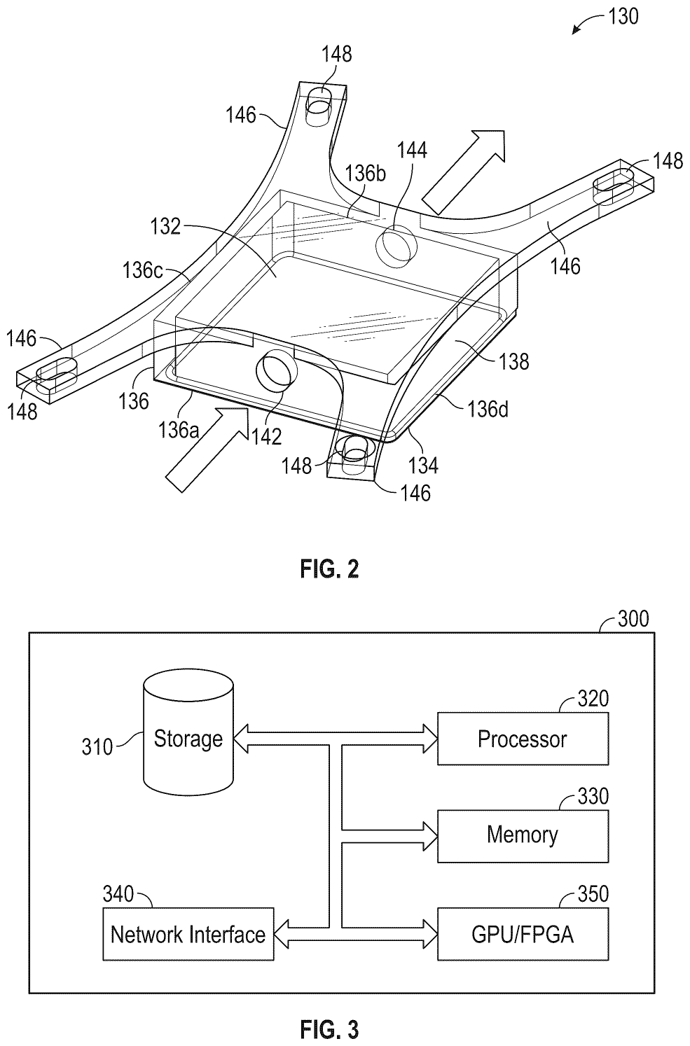

Referring to FIG. 1, a direct liquid contact cooling system 100 is shown. System 100 generally includes an enclosure 130, a radiator 160, a valve 170, a pump 180, and a tubing network 190. Enclosure 130 encapsulates one or more multi-chip modules 122 which may be included on a motherboard 120. Enclosure 130 will be later described in greater detail with reference to FIG. 2. Multi-chip module 122 may instead be any variety of integrated circuit chip or heat-producing electronic component in need of cooling. During use, multi-chip module 122, or any other electronic component, produces heat based at least in part on computational workload. If no means are employed to address fluctuations or increases in temperature, service life and/or performance of the multi-chip module 122 or electronic component may be severely reduced. Therefore, system 100 is configured to cool multi-chip module 122 by circulating a nonconductive fluid 210 which comes into direct contact with multi-chip module 122 to lower temperatures and extend the service life of multi-chip module 122. Fluid 210 may be a nonconductive coolant, in particular, a dielectric fluid such as HFE-7100 or the like. By enabling fluid 210 to pass under enclosure 130, thus directly passing over multi-chip module 122, constraints of traditional indirect contact cooling systems are avoided. For example, cooling systems which use indirect contact between a fluid and a multi-chip module are limited by interfacial thermal resistances between materials. By removing the interface between fluid 210 and multi-chip module 122, these thermal resistance limitations are removed as well, therefore resulting in a significantly more effective and efficient heat transfer path way.

As shown in FIG. 1, system 100 is a closed-loop system, and fluid 210 circulates through the components of system 100 via tubing network 190, as denoted by arrows. Starting from multi-chip module 122, which is disposed within enclosure 130, fluid 210 flows through enclosure 130 and over multi-chip module 122, absorbing the heat dissipated by multi-chip module 122. By permitting direct contact between multi-chip module 122 and fluid 210, heat exchange between multi-chip module 122 and fluid 210 may be optimized using minimal volumes of fluid 210 in comparison to cooling systems which would require full-system immersion. Fluid 210 then exits enclosure 130 and travels to radiator 160 by way of a first portion 192 of tubing network 190. Within radiator 160, fluid 210 disperses thermal energy to outside air through fins of radiator 160 and exits radiator 160 through a second portion 194 of tubing network 190. Fluid 210 is then directed further through tubing network 190 by valve 170. Valve 170 may be a tee valve which permits fluid 210 to travel through one of two paths. Specifically, valve 170 may be a solenoid valve, or any type of valve which may be selectively energized to prevent or allow fluid flow.

In aspects, valve 170 may permit fluid 210 to flow either through a third portion 196 of tubing network 190 or a fourth portion 198 of tubing network 190. Fourth portion 198 of tubing network 190 transports fluid 210 to pump 180, which then propels fluid 210 to a fifth portion 202 of tubing network 190. Valve 170 may instead block fourth portion 198 of tubing network 190 and instead permit fluid 210 to flow to third portion 196 of tubing network 190, in which case fluid 210 bypasses pump 180. Both third portion 196 and fifth portion 202 of tubing network 190 intersect a sixth portion 204 of tubing network 190. Sixth portion 204 of tubing network 190 transports fluid 210 back to motherboard 120, specifically to enclosure 130, to once again absorb thermal energy produced by multi-chip module 122 and re-enter tubing network 190 via first portion 192. Fluid 210 may be continuously circulated through system 100, by natural convection or by forced movement generated by pump 180, as required to effectively cool multi-chip module 122. In aspects, a plurality of enclosures 130, each housing a respective multi-chip module 122, may be connected via tubing network 190 to provide necessary cooling to each multi-chip module 122.

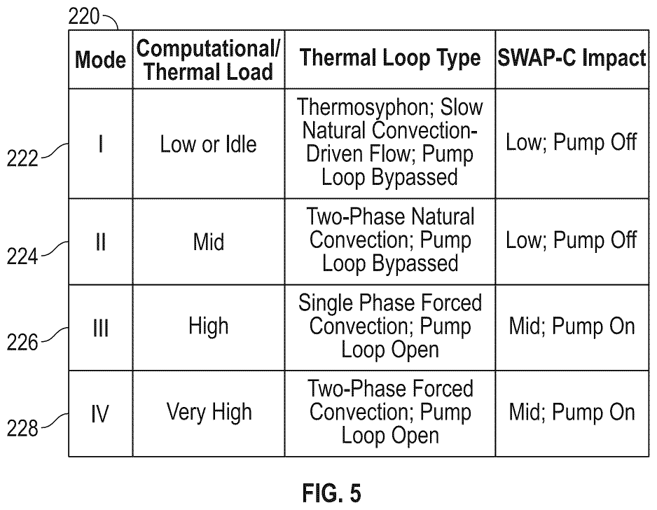

System 100 may additionally include a controller 300, which may control the flow of fluid 210 through certain portions of tubing network 190 in response to the cooling demands of system 100 or the phase or temperature of fluid 210. For example, as will be described in greater detail regarding FIG. 5, controller 300 may cause fluid 210 to either flow through or bypass pump 180 in order to dissipate thermal energy as required. Controller 300 may be integral to motherboard 120 or another component of system 100, as shown, or may be a separate component included in system 100.

Referring to FIG. 2, an illustrative configuration of enclosure 130 is shown. Enclosure 130 generally includes a mounting surface 132 and a lid 134 separated by one or more walls 136 to form a flow cavity 138 therebetween. Flow cavity 138 is configured to house multi-chip module 122, and multi-chip module 122 may be seated on a portion of mounting surface 132 which faces flow cavity 138. Enclosure 130 is further configured to retain fluid 210 within flow cavity 138. To permit fluid 210 to enter and exit flow cavity 138, and therefore directly contact multi-chip module 122 to absorb thermal energy output by multi-chip module 122, enclosure 130 additionally includes an inlet 142 and an outlet 144. Each of inlet 142 and outlet 144 may be disposed on at least one of the one or more walls 136 of enclosure 130. For example, as shown, enclosure 130 may have a generally rectangular shape, and may include a first wall 136a and a second wall 136bopposite first wall 136a. First wall 136a and second wall 136b may be connected by a third wall 136c and an opposing fourth wall 136d. Inlet 142 may be disposed on first wall 136a and outlet 144 may be disposed on second wall 136b to permit fluid 210 to flow in a substantially straight path through flow cavity 138. Other shapes of enclosure 130 are contemplated, for example, enclosure 130 may instead be circular, and alternative arrangements of inlet 142 and outlet 144 on walls 136 are contemplated as well.

Fluid 210 may be provided to enclosure 130 via tubing network 190, for example, first portion 192 of tubing network 190 may connect to outlet 144 and a sixth portion 204 may connect to inlet 142. Enclosure 130 may further include a seal or fluid-tight connection between tubing network 190 and each of inlet 142 and outlet 144 such that fluid 210 is prevented from leaking from enclosure 130 as fluid 210 circulates through system 100.

Enclosure 130 may assume any shape necessary to conform to the geometry of multi-chip module 122 and direct fluid 210 to regions of multi-chip module 122 which contain the highest power density. Fluid 210 is optimized to flow toward high power density regions via geometric features which are included on lid 134 facing flow cavity 138. The geometric features disposed on lid 134 may be protrusions, pockets, or any feature capable of routing fluid 210 toward specified components of multi-chip module 122. The geometric features may be configured to provide a greater or lesser volume of fluid 210 to a particular region of multi-chip module 122 depending upon whether thermal output at the region of multi-chip module 122 is high or low, respectively. The geometric features disposed on lid 134 may also act to direct fluid 210 from inlet 142 toward outlet 144. Due to differing arrangements of high-power density regions of each multi-chip module 122, each lid 134 may include geometric features particular to a respective multi-chip module 122 to ensure efficient cooling and heat dissipation.

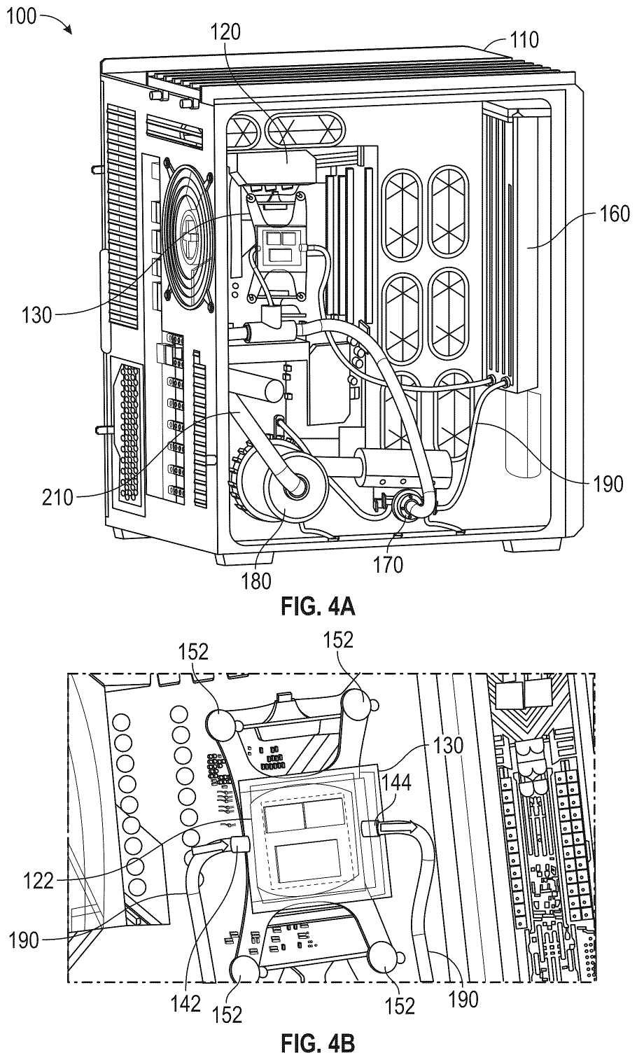

To connect enclosure 130 to motherboard 120, enclosure 130 may additionally include one or more mounting arms 146. Mounting surface 132 may be configured to sit atop motherboard 120, and mounting arms 146 may each comprise a portion of mounting surface 132 which extends outwards from walls 136. In aspects, as shown in FIG. 2, mounting arms 146 may extend from corners formed by walls 136. For example, a first mounting arm 146 may extend from a first corner formed by first wall 136a and third wall 136c, a second mounting arm 146 may extend from a second corner formed by first wall 136a and fourth wall 136d, a third mounting arm 146 may extend from a third corner formed by second wall 136b and third wall 136c, and a fourth mounting arm 146 may extend from a fourth corner formed by second wall 136b and fourth wall 136d. Any number or arrangement of mounting arms 146 to securely fasten enclosure 130 to motherboard 120 may be included on enclosure 130. Each mounting arm 146 may further include a mounting hole 148 configured to accept a fastener 152 (FIG. 4B) to facilitate connection of enclosure 130 to motherboard 120.

As shown in FIG. 3, controller 300 includes a processor 320 connected to a computer-readable storage medium or a memory 330. The computer-readable storage medium or memory 330 may be a volatile type of memory, e.g., RAM, or a non-volatile type of memory, e.g., flash media, disk media, etc. In various aspects of the disclosure, the processor 320 may be another type of processor, such as a digital signal processor, a microprocessor, an ASIC, a graphics processing unit (GPU) configured to display data, or a GUI on a display, a field-programmable gate array (FPGA), or a central processing unit (CPU). In certain aspects of the disclosure, network inference may also be accomplished in systems that have weights implemented as memristors, chemically, or other inference calculations, as opposed to processors.

In aspects of the disclosure, the memory 330 can be random access memory, read-only memory, magnetic disk memory, solid-state memory, optical disc memory, and/or another type of memory. In some aspects of the disclosure, the memory 330 can be separate from the controller 300 and can communicate with the processor 320 through communication buses of a circuit board and/or through communication cables such as serial ATA cables or other types of cables. The memory 330 includes computer-readable instructions that are executable by the processor 320 to operate the controller 300. In other aspects of the disclosure, the controller 300 may include a network interface 340 to communicate with other computers or to a server. A storage device 310 may be used for storing data.

Referring to FIG. 4A, system 100 is shown within housing 110. Here, housing 110 is a computer tower including motherboard 120, enclosure 130 covering multi-chip module 122, valve 170, pump 180, and tubing network 190. Fluid 210 may travel through system 100 via tubing network 190 as previously described regarding FIG. 1. Although system 100 is shown within a computer, system 100 may instead be incorporated into any heat-generating electronic. For example, system 100 may be implemented into servers, data centers, defense electronics and systems, automotive electronics, electric vehicles, power electronics, communications equipment, and any other electronics hardware which experiences high thermal loads and variable workload/environment.

FIG. 4B shows an enlarged view of enclosure 130 as mounted to motherboard 120. Enclosure 130 is connected to motherboard 120 using fasteners 152, which are affixed to motherboard 120 through mounting holes 148 of each mounting arm 146. Fasteners 152 may be screws, may be snap-fit, or may be any other suitable fastener. In aspects, enclosure 130 may be secured to motherboard 120 through use of an adhesive such as glue or epoxy. Multi-chip module 122 is disposed within enclosure 130, and tubing network 190 connects to enclosure 130 to provide fluid 210 for cooling multi-chip module 122 in the direction denoted by arrows. Fluid 210 may enter enclosure 130 through inlet 142, and lid 134 of enclosure 130 may include geometric features which direct fluid 210 over components of multi-chip module 122. After cooling multi-chip module 122, fluid 210 may exit enclosure 130 through outlet 144 and reenter tubing network 190 to dissipate thermal energy acquired from multi-chip module 122.

Turning to FIG. 5, a table of operational modes 220 which may be employed by system 100 via controller 300 is shown. As multi-chip module 122 may not be operating at high power at all times, controller 300 may cause fluid 210 to circulate through different portions of system 100 or circulate at different rates depending at least partially upon the computational load, and therefore the thermal load, of multi-chip module 122. As such, a first mode 222, a second mode 224, a third mode 226, and a fourth mode 228 provide operational modes 220 of system 100 in an increasing order of cooling capacity needed for multi-chip module 122. Modes 220 increase efficiency of system 100 by providing cooling capacity only for what is needed in real time by system 100.

To determine a mode 220 at which system 100 should be operating, controller 300 may determine a phase of fluid 210, for example, liquid, gas, or a combination of liquid and gas. Being a coolant, fluid 210 may evaporate at a lower temperature than, for example, water. That is, as opposed to evaporating at one hundred degrees Celsius, fluid 210 may begin to evaporate at approximately seventy degrees Celsius, or another temperature less than the boiling point of water. Controller 300 may also determine mode 220 of system 100 by determining a temperature of multi-chip module 122 or the operating environment surrounding system 100. Controller 300 may also determine an operating mode 220 of system 100 based at least in part on the computational workload of the multi-chip module 122. Controller 300 may communicate with one or more sensors, for example, thermal sensors, to determine in which mode 220 to operate system 100. Other means of determining an operational mode 220 are contemplated as well. Controller 300 may determine an operational mode 220 in real time, in predetermined intervals of time, or in response to the occurrence of a predetermined event.

In first mode 222, multi-chip module 122 may be idle, and therefore may experience zero or nominal computational load, or may be operating at a low power and consequently only have a low computational load. Therefore, in first mode 222, multi-chip module 122 may maintain a relatively low temperature or radiate low amounts of heat. In first mode 222, fluid 210 moves through system 100 via thermosyphon, that is, by natural convection. Heat produced by multi-chip module 122 creates a temperature difference through tubing network 190, thereby causing heated fluid 210 to flow slowly toward cooler areas of system 100. In first mode 222, valve 170 prevents fluid 210 from entering fourth portion 198 of tubing network 190, and therefore pump 180 remains powered off. In first mode 222, pump 180 does not propel fluid 210 through tubing network 190. The path of travel of fluid 210 in first mode 222 begins at enclosure 130, where fluid 210 is heated by multi-chip module 122. Fluid 210 then travels to first portion 192 of tubing network 190 to radiator 160, where heat is dissipated to the outside environment. Fluid 210 then flows through second portion 194 of tubing network 190 to valve 170. Valve 170 blocks fluid 210 from entering pump 180 and instead permits fluid 210 to enter third portion 196, then sixth portion 204 of tubing network 190, returning fluid 210 to enclosure 130. In first mode 222, system 100 has a minimal adverse impact on size, weight, power, and cost (“SWaP-C”), as pump 180 is not powered and therefore consumes no electricity.

In second mode 224, multi-chip module 122 may have a mid-level computational load, and as a result may produce more heat than in first mode 222. In producing more heat, amounts of fluid 210 may be brought to a boiling point and begin to separate into liquid and gas components. In second mode 224, partially liquid and partially gaseous fluid 210 is transported through system 100 by natural convection (i.e., two-phase natural convection), and may flow at a greater rate through system 100 as the temperature difference through tubing network 190 is increased from the first mode 222. Similar to first mode 222, in second mode 224, valve 170 prevents fluid 210 from entering fourth portion 198 of tubing network 190. Therefore, pump 180 remains powered off and does not drive circulation of fluid 210. In second mode 224, fluid 210 travels the same path as in first mode 222. Beginning at enclosure 130, where fluid 210 is heated by multi-chip module 122, the path of travel of fluid 210 in second mode 224 then moves through first portion 192 of tubing network 190 to radiator 160 to release heat to the atmosphere. Due to increased thermal and computational load in second mode 224, a fan or another cooling mechanism within radiator 160 may be activated by controller 300 to facilitate cooling of fluid 210 and condensation of fluid 210 into a single phase. Fluid 210 then travels through second portion 194 of tubing network 190 to valve 170, where fluid 210 is routed to third portion 196, then sixth portion 204 of tubing network 190, and finally returned to enclosure 130. Like first mode 222, in second mode 224, fluid 210 bypasses pump 180. Also similar to first mode 222, in second mode 224, system 100 has a minimal SWaP-C impact, due to lack of operation of pump 180.

In third mode 226, multi-chip module 122 may have a high computational load, producing enough heat to require forced convection in order to provide effective cooling to multi-chip module 122. In third mode 226, fluid 210 may return to a single phase (e.g., liquid), and may circulate through system 100 via pump 180. In third mode 226, valve 170 permits fluid 210 to enter fourth portion 198 of tubing network 190 as well as pump 180. In third mode 226, pump 180 is activated to propel fluid 210 through system 100, therefore providing increased cooling capabilities to multi-chip module 122. The path of travel of fluid 210 in third mode 226 begins at enclosure 130 with multi-chip module 122 heating fluid 210. Fluid 210 then travels to radiator 160 via first portion 192 of tubing network 190 and disperses heat through fins of radiator 160. Fluid 210 is then transported through second portion 194 of tubing network 190 to valve 170, where valve 170 transports fluid 210 therethrough to fourth portion 198 of tubing network 190. In third mode 226, valve 170 permits fluid 210 to reach pump 180 via third portion 196 of tubing network 190. Fluid 210 is driven to circulate through system 100 by pump 180, which directs fluid 210 to fifth portion 202 and then sixth potion 204 of tubing network 190 before again entering enclosure 130. Due to operation of pump 180, which consumes electricity, third mode 226 has a mid-level impact on the SWaP-C of system 100, but still runs efficiently due to the fact that pump 180 does not run continually, and only the power that is needed for cooling is consumed.

In fourth mode 228, multi-chip module 122 may have the highest computational load, and may produce enough heat that, even with forced convection provided by pump 180, amounts of fluid 210 may separate into two phases. In fourth mode 228, partially liquid and partially gaseous fluid 210 is pushed through system 100 by pump 180 (i.e., two-phase forced convection), and may flow at a greater rate through system 100 than in third mode 226 due to increased cooling requirements of multi-chip module 122. Like second mode 224, in fourth mode 228, a fan or another cooling mechanism within radiator 160 may be activated by controller 300 to facilitate cooling and condensation of fluid 210. To further address cooling needs, similar to third mode 226, valve 170 permits fluid 210 to enter fourth portion 198 of tubing network 190 to flow through pump 180. In fourth mode 228, pump 180 is powered on to drive fluid 210 through system 100 and thereby increase cooling of multi-chip module 122 as required to effectively distribute the high thermal load output by multi-chip module 122. In fourth mode 228, fluid 210 begins at enclosure 130, where fluid 210 is heated by thermal energy produced by multi-chip module 122. Then, fluid 210 enters radiator 160 by first portion 192 of tubing network 190 to cool fluid 210 and exits to second portion 194 of tubing network 190. There, fluid 210 enters valve 170, which permits fluid 210 to enter pump 180 by way of fourth portion 198 of tubing network 190. In fourth mode 228, valve 170 prevents fluid 210 from entering third portion 196 of tubing network 190 and therefore prevents fluid 210 from evading pump 180. After being driven by pump 180, fluid 210 is pushed through fifth portion 202 and sixth portion 204 of tubing network 190 to then reenter enclosure 130. Again, due to operation of pump 180, fourth mode 228 has a mid-level impact on the SWaP-C of system 100 but retains efficiency by operating in fourth mode 228 only when required.

As previously noted, controller 300 selects mode 220 of operation according to temperature data determined from multi-chip modules 122 as well as from the operating environment surrounding system 100. According to temperature values and workload reported to controller 300 by multi-chip module 122 and optional environmental sensors, controller 300 implements real-time response and mode-selection to changing workload or external conditions. Thus, system 100 provides efficiency, operational flexibility, and automated sense-and-respond capabilities such that SWaP-C capital is not wasted unnecessarily by running system 100 in an operating mode 220 above what is necessary at that time.

Certain aspects of the present disclosure may include some, all, or none of the above advantages and/or one or more other advantages readily apparent to those skilled in the art from the drawings, descriptions, and claims included herein. Moreover, while specific advantages have been enumerated above, the various aspects of the present disclosure may include all, some, or none of the enumerated advantages and/or other advantages not specifically enumerated above.

The aspects disclosed herein are examples of the disclosure and may be embodied in various forms. For instance, although certain aspects herein are described as separate aspects, each of the aspects herein may be combined with one or more of the other aspects herein.

Specific structural and functional details disclosed herein are not to be interpreted as limiting, but as a basis for the claims and as a representative basis for teaching one skilled in the art to variously employ the present disclosure in virtually any appropriately detailed structure. Like reference numerals may refer to similar or identical elements throughout the description of the figures.

The phrases “in an aspect,” “in aspects,” “in various aspects,” “in some aspects,” or “in other aspects” may each refer to one or more of the same or different example Aspects provided in the present disclosure. A phrase in the form “A or B” means “(A), (B), or (A and B).” A phrase in the form “at least one of A, B, or C” means “(A); (B); (C); (A and B); (A and C); (B and C); or (A, B, and C).”

It should be understood that the foregoing description is only illustrative of the present disclosure. Various alternatives and modifications can be devised by those skilled in the art without departing from the disclosure. Accordingly, the present disclosure is intended to embrace all such alternatives, modifications, and variances. The aspects described with reference to the attached drawing figures are presented only to demonstrate certain examples of the disclosure. Other elements, steps, methods, and techniques that are insubstantially different from those described above and/or in the appended claims are also intended to be within the scope of the disclosure.

What is claimed is:

1. A system for cooling an electronic component, comprising:
an enclosure configured to house an electronic component and to permit a fluid to directly contact the electronic component;
a radiator configured to cool the fluid;
a pump;
a valve, wherein the valve selectively permits passage of the fluid to the pump; and
a tubing network configured to circulate the fluid from the enclosure to at least one of the radiator, the valve, or the pump.

2. The system of claim 1, wherein the enclosure comprises an inlet and an outlet, and wherein:
a first portion of the tubing network connects the outlet of the enclosure and the radiator,
a second portion of the tubing network connects the radiator and the valve, and
a third portion of the tubing network connects the valve and the inlet of the enclosure.

3. The system of claim 2, wherein:
a fourth portion of the tubing network connects the valve and the pump, and
a fifth portion of the tubing network connects the pump and the inlet of the enclosure, wherein the third portion of the tubing network and the fifth portion of the tubing network intersect.

4. The system of claim 3, wherein the valve permits the fluid to enter either the third portion of the tubing network or the fourth portion of the tubing network based at least in part on at least one of a computational or thermal load of the electronic component.

5. The system of claim 1, wherein the valve permits the fluid to enter the pump based at least in part on at least one of a computational or thermal load of the electronic component.

6. The system of claim 1, wherein the pump is powered on to propel the fluid through the tubing network based at least in part on at least one of a computational or thermal load of the electronic component.

7. The system of claim 1, wherein the enclosure is configured to provide a greater volume of fluid to a first portion of the electronic component having a greater power density in comparison to a second portion of the electronic component having a lower power density.

8. The system of claim 1, further comprising:
a processor; and
a memory, including instructions stored thereon, which, when executed by the processor cause the system to:
determine at least one of a computational or thermal load of the electronic component; and
based at least in part on at least one of the determined computational or thermal load of the electronic component, operate the valve and the pump in accordance with a predetermined mode.

9. The system of claim 8, wherein the instructions, when executed by the processor, further cause the system to:
if the determined computational or thermal load of the electronic component is low-to mid-level, operate in a first mode, wherein:
the valve is actuated to prevent the fluid from entering the pump via the tubing network; and
the pump is powered off.

10. The system of claim 8, wherein the instructions, when executed by the processor, further cause the system to:
if the determined computational or thermal load of the electronic component is high, operate in a second mode, wherein:
the valve is actuated to permit the fluid to enter the pump via the tubing network; and
the pump is powered on.

11. An enclosure for use with a cooling system for an electronic component, comprising:
a mounting surface configured for mounting an electronic component;
one or more walls protruding from the mounting surface; and
a lid disposed on the one or more walls, wherein the one or more walls separate the mounting surface and the lid to form a flow cavity therebetween, wherein the flow cavity is configured and dimensioned to house the electronic component, and wherein the flow cavity is configured to pass a fluid over the electronic component to cool the electronic component.

12. The enclosure of claim 11, wherein the enclosure further comprises an inlet to permit ingress of the fluid, the inlet disposed on a first wall of the one or more walls.

13. The enclosure of claim 11, wherein the enclosure further comprises an outlet to permit egress of the fluid, the outlet disposed on a second wall of the one or more walls.

14. The enclosure of claim 11, wherein the mounting surface further includes one or more arms for attachment to a surface.

15. The enclosure of claim 14, wherein the one or more arms extend outward from the one or more walls of the enclosure.

16. The enclosure of claim 14, wherein a hole is defined through at least an arm of the one or more arms, wherein the hole is configured to receive a fastener.

17. The enclosure of claim 11, wherein the lid, on a surface facing the flow cavity, further includes a geometric feature configured to direct the fluid toward a portion of the electronic component having a high-power density.

18. A method of cooling an electronic component within an enclosure, wherein: the enclosure is configured to permit contact between the electronic component and a fluid; a tubing network is configured to circulate the fluid through the enclosure, a radiator, and at least one of a valve or a pump, before returning the fluid to the enclosure; and the valve selectively connects the tubing network to the pump, the method comprising:
determining at least one of a computational or thermal load of the electronic component; and
based at least in part on the determined computational or thermal load of the electronic component, operating the valve and the pump in accordance with a predetermined mode.

19. The method of claim 18, further comprising, if the determined computational or thermal load of the electronic component is low-to mid-level, operating the valve and the pump in a first mode, the first mode comprising:
circulating the fluid from the enclosure through the radiator;
actuating the valve to prevent the fluid from entering the pump;
powering the pump off such that the fluid is circulated through the tubing network via natural convection; and
returning the fluid to the enclosure from the valve.

20. The method of claim 18, further comprising, if the determined computational or thermal load of the electronic component is high, operating the valve and the pump in a second mode, the second mode comprising:
circulating the fluid from the enclosure through the radiator;
actuating the valve to permit the fluid to enter the pump;
powering the pump to propel the fluid through the tubing network; and
returning the fluid to the enclosure from the pump.
